(19) United States
(12) Patent Application Publication
(10) Pub. No.: US 2025/0194011 A1
(43) Pub. Date: Jun. 12, 2025

(54) PRINTED CIRCUIT BOARD AND SEMICONDUCTOR PACKAGE HAVING THE SAME

(71) Applicant: SAMSUNG ELECTRONICS CO., LTD., SUWON-SI (KR)

(72) Inventor: Eunhye Lee, Suwon-si (KR)

(21) Appl. No.: 18/970,724

(22) Filed: Dec. 5, 2024

(30) Foreign Application Priority Data
Dec. 12, 2023 (KR) 10-2023-0180097

(51) Int. Cl. H05K 1/11; H01L 23/00; H01L 23/498; H01L 25/065; H05K 1/02; H05K 1/18; H05K 3/40; H10B 80/00

(52) U.S. Cl. CPC H05K 1/115; H05K 1/0219; H05K 1/181; H01L 23/49822; H01L 23/49838; H01L 24/14; H01L 24/16; H01L 25/0652; H01L 2224/14131; H01L 2224/16227; H01L 2924/14361; H05K 3/4076; H05K 2201/09227; H05K 2201/095; H10B 80/00

(57) ABSTRACT

The invention provides a printed circuit board and a semiconductor package having the same, the printed circuit board includes traces disposed on respective upper and lower surfaces of the base layers and disposed on different vertical levels from a lowermost layer to an uppermost layer, and through vias connecting traces disposed on different vertical levels to each other and each extending in a vertical direction to pass through at least one of the base layers. The through vias include a first through via connecting the traces at the lowermost layer and the uppermost layer to each other, and a second through via connecting respective traces at adjacent intermediate layers between the lowermost layer and the uppermost layer to each other. The first through via passes through the inside of the second through via in the vertical direction, and the first through via is insulated from the second through via.

### CROSS-REFERENCE TO RELATED APPLICATION

This application claims priority under 35 U.S.C. § 119 to Korean Patent Application No. 10-2023-0180097, filed on Dec. 12, 2023, in the Korean Intellectual Property Office, the disclosure of which is incorporated by reference herein in its entirety.

### TECHNICAL FIELD

The present disclosure relates to semiconductors and, more specifically, to printed circuit boards and semiconductor packages including the same.

### DISCUSSION OF THE RELATED ART

In recent electronic product markets, demand for mobile or portable devices has increased rapidly, and accordingly, miniaturization and weight reduction of electronic components mounted on such electronic products have been continuously pursued. For this purpose, a semiconductor package mounted on the electronic products is designed to have a smaller volume and process high-capacity data. Because semiconductor chips that are so-packaged are mounted on a printed circuit board, electrical reliability of these chips is important. Also important is circuit design freedom, which is the concept that the engineers that design the circuits should have as few restraints as possible so that they may come up with the best possible design.

### SUMMARY

A printed circuit board in which K base layers are stacked (where K is an integer of 3 or more), the printed circuit board includes K+1 traces disposed on respective upper and lower surfaces of each of the base layers and disposed on different vertical levels from a lowermost layer of the base layers to an uppermost layer of the base layers. Through vias connect traces disposed on different vertical levels to each other and each extending in a vertical direction passing through at least one of the base layers. The through vias include a first through via connecting the traces a t the lowermost layer and the uppermost layer to each other, and a second through via connecting respective traces at adjacent intermediate layers between the lowermost layer and the uppermost layer to each other, and the first through via passes through the inside of the second through via in the vertical direction, and the first through via is insulated from the second through via.

A printed circuit board includes a substrate base including a plurality of base layers, a plurality of traces disposed on respective upper and lower surfaces of each of the plurality of base layers, and a plurality of through vias each passing through at least one of the plurality of base layers and contacting the plurality of traces. One of the plurality of through vias has a cylindrical shape, and another one of the plurality of through vias has a hollow cylinder shape surrounding the cylindrical shape.

A semiconductor package includes a printed circuit board having a chip mounting area and a peripheral area surrounding the chip mounting area. At least one semiconductor chip has a first surface and a second surface opposite to the first surface. The at least one semiconductor chip includes a chip pad disposed on the first surface, and being mounted in the chip mounting area such that the first surface faces an upper surface of the printed circuit board. A connection bump is attached to the chip pad. The printed circuit board includes base layers stacked in three or more layers, traces disposed on respective upper and lower surfaces of the base layers and disposed on different vertical levels from a lowermost layer to an uppermost layer. Through vias connect the traces disposed on different vertical levels to each other and each extend in a vertical direction and pass through at least one of the base layers. The through vias include a first through via connecting traces at the lowermost layer and the uppermost layer to each other, and a second through via connecting respective traces at adjacent intermediate layers between the lowermost layer and the uppermost layer to each other. The first through via passes through the inside of the second through via in the vertical direction.

### BRIEF DESCRIPTION OF THE DRAWINGS

Embodiments of the present disclosure will be more clearly understood from the following detailed description taken in conjunction with the accompanying drawings in which:

FIG. 1 is a schematic perspective view of a main board including a semiconductor package according to an embodiment;

FIG. 2 is a perspective view of a semiconductor package including a printed circuit board, according to an embodiment;

FIG. 3 is a cross-sectional view of a printed circuit board according to an embodiment;

FIG. 4 is a plan view of a region AA of FIG. 3;

FIG. 5 is a perspective view of each wiring layer of FIG. 3;

FIG. 6 is a cross-sectional view of a printed circuit board according to a derivative embodiment of FIG. 3;

FIG. 7 is a cross-sectional view of a printed circuit board according to an embodiment;

FIG. 8 is a plan view of a region BB of FIG. 7;

FIG. 9 is a perspective view of each wiring layer of FIG. 7;

FIG. 10 is a cross-sectional view of a printed circuit board according to a derivative embodiment of FIG. 7;

FIG. 11 is a flowchart of a method of manufacturing a printed circuit board device, according to an embodiment;

FIGS. 12 through 20 are cross-sectional views illustrating a method of manufacturing a printed circuit board, according to an embodiment;

FIG. 21 is a block diagram of a detachable storage device;

FIGS. 22 and 23 are diagrams illustrating examples of various form factors defining a printed circuit board mounted on the detachable storage device of FIG. 21; and

FIG. 24 is a plan view of a printed circuit board according to an embodiment.

### DETAILED DESCRIPTION OF THE EMBODIMENTS

Embodiments of the inventive concept will now be described more fully with reference to the accompanying drawings.

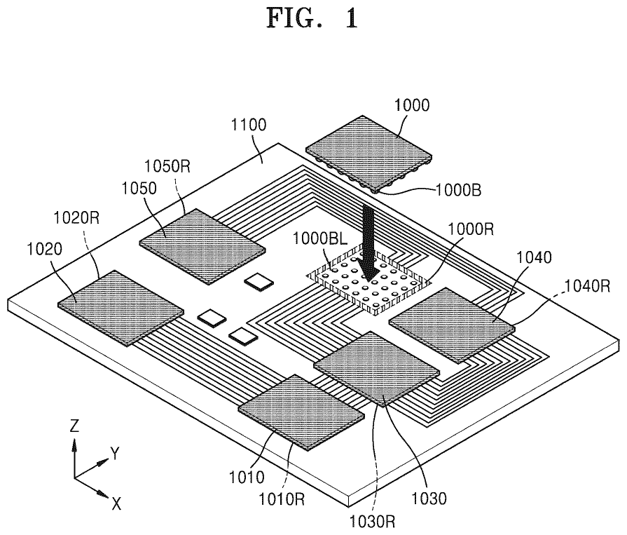

FIG. 1 is a schematic perspective view of a main board including a semiconductor package according to an embodiment.

Referring to FIG. 1, a main board 1100 may include various pieces of hardware mounted on its upper surface.

The various pieces of hardware included in the main board 1100 may be mounted in respective dedicated areas. For example, the main board 1100 may include a dedicated area 1000R for a storage device 1000, a dedicated area 1010R for a host 1010, a dedicated area 1020R for a memory 1020, a dedicated area 1030R for a chipset 1030, a dedicated area 1040R for a graphics processing unit 1040, a dedicated area 1050R for a network module 1050, etc. These dedicated areas may be electrically connected to each other through various wires provided on the main board 1100.

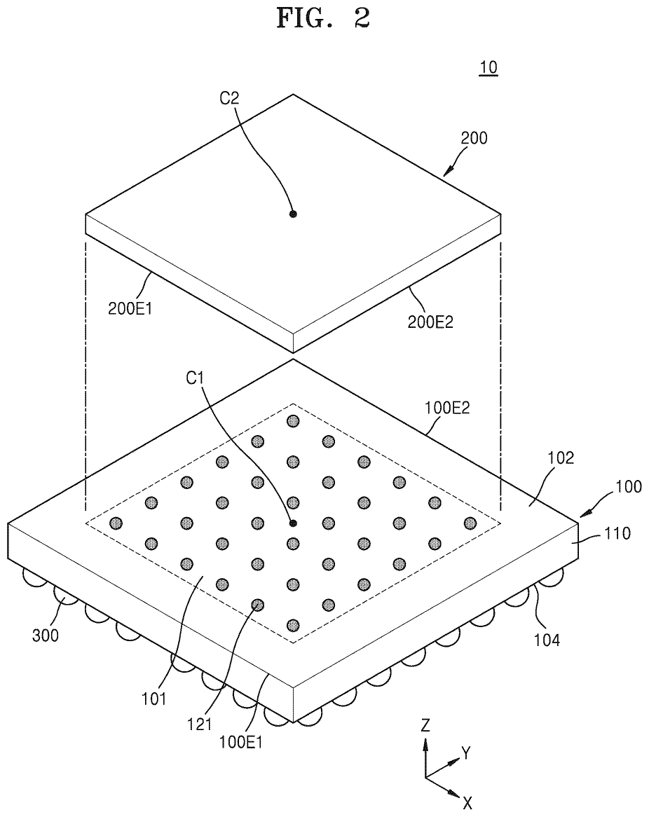

According to some embodiments, the storage device 1000, the host 1010, the memory 1020, the chipset 1030, the graphics processing unit 1040, and/or the network module 1050 may be provided as a semiconductor package 10 (see FIG. 2) of a ball grid array (BGA) type. For example, the storage device 1000 may include solder balls 1000B as external connection terminals, and the storage device 1000 may be mounted on the main board 1100 so that ball lands 1000BL disposed in the dedicated area 1000R are combined with the solder balls 1000B. The storage device 1000 may be mounted on the main board 1100 by using surface mounting technology.

The storage device 1000 may be provided as one or in plural. According to some embodiments, the storage device 1000 may be mounted on different surfaces of the main board 1100. For example, one storage device 1000 may be mounted on the upper surface of the main board 1100, and another storage device 1000 may be mounted on a bottom surface of the main board 1100.

The storage device 1000 may transmit a program code to the host 1010 by using a sideband protocol. According to some embodiments, a side band protocol may further include communication protocols such as I2C, MCTP, SMBus, etc., which are additionally provided, in addition to communication protocols provided for a normal operation. A detailed description of the components included within the storage device 1000 will be described later.

FIG. 2 is a perspective view of a semiconductor package including a printed circuit board, according to an embodiment.

Referring to FIG. 2, a semiconductor package 10 may include a printed circuit board 100, and a semiconductor chip 200 mounted on the printed circuit board 100.

The printed circuit board 100 may be a package substrate. The printed circuit board 100 may include a substrate base 110, upper connection pads 121 on an upper surface 102 of the printed circuit board 100, and lower connection pads on a lower surface 104 of the printed circuit board 100.

The substrate base 110 may form the overall outer appearance of the printed circuit board 100, and may be formed of, for example, phenol resin, epoxy resin, and/or polyimide. An internal interconnection structure (e.g., a trace and a through via) for electrically connecting the upper connection pads 121 to the lower connection pads may be provided inside the substrate base 110. The upper connection pads 121 may be connected to a conductive connection structure on a lower surface of the semiconductor chip 200, and the lower connection pads may be connected to solder balls 300, which are external connection terminals.

The printed circuit board 100 may include a mounting area 101 on which the semiconductor chip 200 is mounted. The mounting area 101 is an area where the semiconductor chip 200 is disposed, and thus the mounting area 101 and the semiconductor chip 200 may substantially overlap each other in a vertical direction (e.g., Z direction). Because the mounting area 101 overlaps the semiconductor chip 200 in the vertical direction (e.g., Z direction), the mounting area 101 may have the same shape and size as the semiconductor chip 200.

When a first horizontal direction (e.g., X direction) is defined as a direction parallel to a first end 200E1 of the semiconductor chip 200 and a second horizontal direction (e.g., Y direction) is defined as a direction parallel to a second end 200E2 of the semiconductor chip 200, a center point C1 of the mounting area 101 and a center point C2 of the semiconductor chip 200 may coincide with each other on a plane parallel to the first horizontal direction (e.g., X direction) and the second horizontal direction (e.g., Y direction).

A width of the semiconductor chip 200 in the first horizontal direction (e.g., X direction) may be substantially equal to that of the mounting area 101 in the first horizontal direction (e.g., X direction), and a width of the semiconductor chip 200 in the second horizontal direction (e.g., Y direction) may be substantially equal to that of the mounting area 101 in the second horizontal direction (e.g., Y direction).

According to some embodiments, the semiconductor chip 200 may be mounted on the mounting area 101 of the printed circuit board 100 by using a flip chip method. For example, the semiconductor chip 200 may be connected to the upper connection pads 121 of the printed circuit board 100 through the conductive connection structure, for example, through solder bumps, but embodiments are not necessarily limited thereto. According to embodiments, the semiconductor chip 200 may be mounted on the mounting area 101 of the printed circuit board 100 by using bonding wires.

The semiconductor chip 200 may be a logic chip or a memory chip. The memory chip may be, for example, a volatile memory semiconductor chip, such as a Dynamic Random Access Memory (DRAM) or a Static Random Access Memory (SRAM), or a non-volatile memory semiconductor chip, such as a Phase-change Random Access Memory (PRAM), a Magnetoresistive Random Access Memory (MRAM), a Ferroelectric Random Access Memory (FeRAM), or a Resistive Random Access Memory (RRAM). The logic chip may be, for example, a microprocessor, an analog device, a digital signal processor, or an application processor.

In FIG. 2, the semiconductor package 10 is shown as including one semiconductor chip 200. However, the semiconductor package 10 may include a plurality of semiconductor chips 200. According to some embodiments, the semiconductor chip 200 may be a chip stack in which a plurality of semiconductor chips 200 are vertically stacked. For example, the semiconductor chip 200 may be a high bandwidth memory (HBM).

The center point C1 of the printed circuit board 100 may substantially coincide with the center point C1 of the mounting area 101 and/or the center point C2 of the semiconductor chip 200, on the plane parallel to the first horizontal direction (e.g., X direction) and the second horizontal direction (e.g., Y direction). In this case, when an end of the printed circuit board 100 adjacent to the first end 200E1 of the semiconductor chip 200 is defined as the first end 100E1 of the printed circuit board 100, and an end of the printed circuit board 100 opposite to the first end 100E1 is defined as the second end 100E2 of the printed circuit board 100, the center point C1 of the printed circuit board 100 may be disposed at substantially the same distance from the first end 100E1 of the printed circuit board 100 as from the second end 100E2 of the printed circuit board 100.

An underfill may be interposed between the printed circuit board 100 and the semiconductor chip 200. For example, the underfill that fills a space between the printed circuit board 100 and the semiconductor chip 200 may be formed through an underfill process. The underfill may be filled between the printed circuit board 100 and the semiconductor chip 200, and may surround a connection bump, which is a conductive connection structure interposed between the printed circuit board 100 and the semiconductor chip 200.

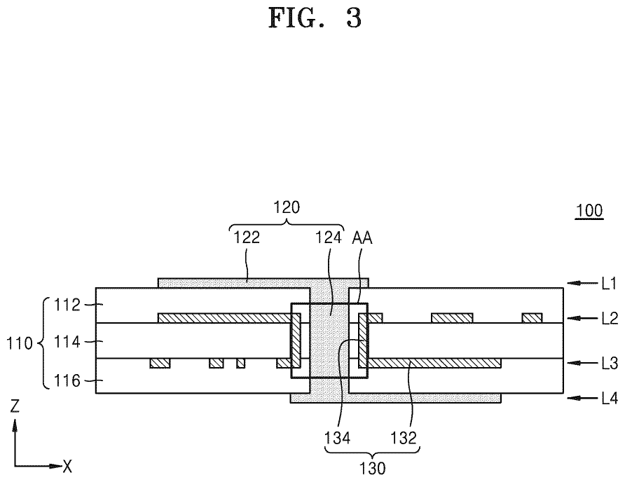

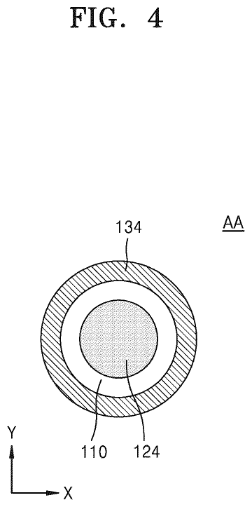

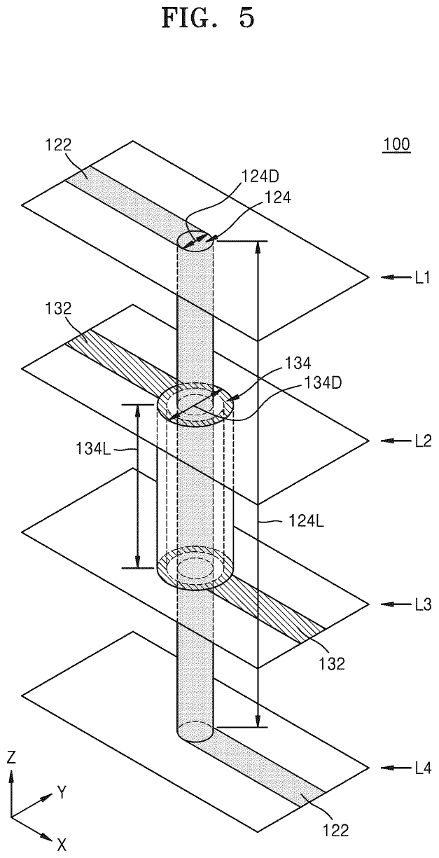

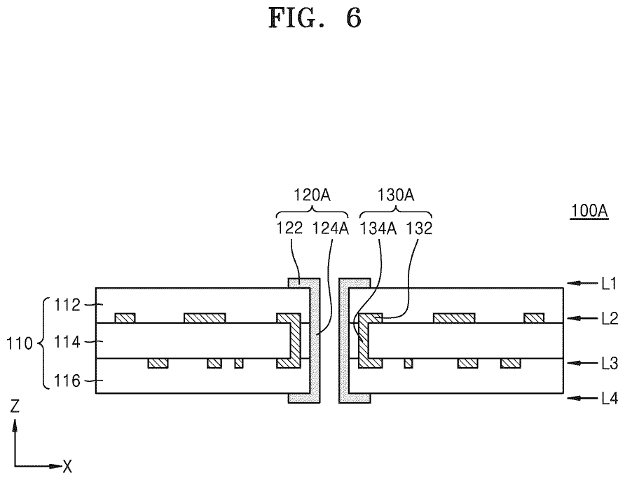

FIG. 3 is a cross-sectional view of a printed circuit board according to an embodiment, FIG. 4 is a plan view of a region AA of FIG. 3, and FIG. 5 is a perspective view of each wiring layer of FIG. 3. FIG. 6 is a cross-sectional view of a printed circuit board according to a derivative embodiment of FIG. 3.

Referring to FIGS. 3 through 5 together, the printed circuit board 100 may have a substrate base 110, a signal wire 120, and a ground wire 130, and may include first, second, third, and fourth wiring layers L1, L2, L3, and L4.

For convenience of explanation, only a portion of the printed circuit board 100 of the inventive concept is shown in the drawings. However, those skilled in the art will be able to fully understand the technical idea of the inventive concept.

The printed circuit board 100 may include a substrate base 110 in which K (where K is an integer equal to or greater than 3) base layers 112, 114, and 116 are stacked from a lowest layer to an uppermost layer in the vertical direction (e.g., Z direction). The printed circuit board 100 may also include traces 122 and 132 disposed on each of the base layers 112, 114, and 116, and through vias 124 and 134 each extending in the vertical direction (e.g., Z direction) to pass through at least one of the base layers 112, 114, and 116 to electrically connect the traces 122 and 132 disposed at different vertical levels, to each other.

The substrate base 110 may be formed by stacking the three base layers 112, 114, and 116. The four first, second, third, and fourth wiring layers L1, L2, L3, and L4 may be disposed on respective upper and lower surfaces of the three base layers 112, 114, and 116. For convenience of explanation, the three base layers 112, 114, and 116 and the four wiring layers L1, L2, L3, and L4 are shown. However, the number of base layers in the substrate base 110 and the number of wiring layers in the substrate base 110 are not necessarily limited thereto.

For example, when the substrate base 110 is formed by stacking a first base layer 112, a second base layer 114, and a third base layer 116, the first, second, third, and fourth wiring layers L1, L2, L3, and L4 may include the first wiring layer L1 disposed on the upper surface of the first base layer 112, the second wiring layer L2 disposed on an interface between the lower surface of the first base layer 112 and the upper surface of the second base layer 114, the third wiring layer L3 disposed on an interface between the lower surface of the second base layer 114 and the upper surface of the third base layer 116, and the fourth wiring layer L4 disposed on the lower surface of the third base layer 116.

The plurality of traces 122 and 132 disposed in the first, second, third, and fourth wiring layers L1, L2, L3, and L4 may be formed on the substrate base 110. According to some embodiments, the plurality of traces 122 and 132 may include signal traces 122 and ground traces 132. The plurality of traces 122 and 132 may be formed of, for example, copper (Cu), nickel (Ni), and/or beryllium copper.

According to some embodiments, the signal traces 122 may be disposed on the first wiring layer L1 and the fourth wiring layer L4. The ground traces 132 may be disposed on the second wiring layer L2 and the third wiring layer L3. For example, the signal traces 122 may be disposed on uppermost and lowermost surfaces of the substrate base 110, and the ground traces 132 may be disposed inside the substrate base 110.

According to some embodiments, the signal trace 122 of the first wiring layer L1 and the ground trace 132 of the second wiring layer L2 may overlap each other in the vertical direction (e.g., Z direction), and may each extend in the first horizontal direction (e.g., X direction). The signal trace 122 of the fourth wiring layer L4 and the ground trace 132 of the third wiring layer L3 may overlap each other in the vertical direction (e.g., Z direction), and may each extend in the first horizontal direction (e.g., X direction). The signal trace 122 of the first wiring layer L1 and the signal trace 122 of the fourth wiring layer L4 may each extend in different horizontal directions (e.g., +X and −X directions). Accordingly, the ground trace 132 of the second wiring layer L2 and the ground trace 132 of the third wiring layer L3 may each extend in different horizontal directions (e.g., +X and −X directions).

A plurality of through vias 124 and 134 electrically connecting the traces 122 and 132 disposed in the first, second, third, and fourth wiring layers L1, L2, L3, and L4 to each other may be formed in the substrate base 110. According to some embodiments, the plurality of through vias 124 and 134 may include a signal through via 124 and a ground through via 134. The plurality of through vias 124 and 134 may be formed of, for example, copper (Cu), nickel (Ni), and/or beryllium copper.

The plurality of through vias 124 and 134 may include a signal through via 124 connecting the signal trace 122 of the first wiring layer L1 to the signal trace 122 of the fourth wiring layer L4, and a ground through via 134 connecting the ground trace 132 of the second wiring layer L2 to the ground trace 132 of the third wiring layer L3.

According to some embodiments, the signal through via 124 may be formed in a cylindrical shape having a first length 124L in the vertical direction (e.g., Z direction) and a first diameter 124D in the horizontal direction (e.g., X and Y directions). Compared to this, the ground through via 134 may be formed in a hollow cylinder shape having a second length 134L less than the first length 124L in the vertical direction (e.g., Z direction) and a second diameter 134D greater than the first diameter 124D in the horizontal direction (e.g., X and Y directions). For example, each of the inner diameter and the outer diameter of the ground through via 134 may be designed to be greater than the first diameter 124D of the signal through via 124.

According to some embodiments, the signal through via 124 may pass through the inside of the ground through via 134 in the vertical direction (e.g., Z direction). The signal through via 124 may be insulated from the ground through via 134. For example, the substrate base 110 or an insulating material (e.g., phenol resin, epoxy resin, or polyimide) included within the substrate base 110 may be disposed between the signal through via 124 and the ground through via 134.

A solder resist layer covering at least a portion of the signal trace 122 may be formed on an upper surface of the substrate base 110. A solder resist layer covering at least a portion of the signal trace 122 may be formed on a lower surface of the substrate base 110. Respective portions of the signal traces 122 exposed without being covered by the solder resist layer may be signal wirings of the printed circuit board 100, respectively. An organic solderability preservative (OSP) may be applied to the respective upper surfaces of the signal traces 122.

The semiconductor chip 200 (see FIG. 2) may be mounted on the upper surface 102 of the printed circuit board 100. For example, the upper surface 102 of the printed circuit board 100 may be a chip mounting surface. Solder balls 300, which are external connection terminals, may be attached onto the lower surface 104 of the printed circuit board 100. For example, the lower surface 104 of the printed circuit board 100 may be a connection terminal attaching surface. The semiconductor chip 200 (see FIG. 2) may be electrically connected to the printed circuit board 100 via connection bumps.

In recent electronic product markets, demand for mobile or portable devices has increased rapidly, and accordingly, miniaturization and weight reduction of electronic components mounted on such electronic products have been continuously required. For this purpose, the semiconductor package (see FIG. 2) mounted on the electronic products is required to have a smaller volume and process high-capacity data. Because the semiconductor chip 200 (see FIG. 2) included within this semiconductor package 10 (see FIG. 2) is mounted on the printed circuit board 100, it is important to increase electrical reliability and circuit design freedom of the printed circuit board 100 in the semiconductor package 10 (see FIG. 2).

Furthermore, because a circuit needs to be connected in the vertical direction (e.g., Z direction) from the upper surface 102 of the printed circuit board 100 to the lower surface 104 of the printed circuit board 100, appropriate through vias 124 and 134 are needed. As the printed circuit board 100 consists of a plurality of base layers 112, 114, and 116, a plurality of through vias 124 and 134 are formed between the base layers 112, 114, and 116, and the number of through vias 124 and 134 is determined depending on the integration of the circuit.

When the through vias 124 and 134 are arranged side by side in different horizontal directions (e.g., X and Y directions) of the printed circuit board 100, the placement area is large due to the increased through vias 124 and 134. This may cause a decrease in space securement of the printed circuit board 100 and the degree of freedom with respect to circuit design. In addition, when the signal trace 122 and the ground trace 132 extend in different horizontal directions (for example, +X and −X directions), a shielding effect for the signal trace 122 is reduced, leading to a decrease in electrical reliability.

To address these problems, in the printed circuit board 100, according to the inventive concept, the signal through via 124 may pass through the inside of the ground through via 134 in the vertical direction (e.g., Z direction). In this case, even when the number of through vias 124 and 134 increases, the placement area may be efficiently managed, and thus space securement of the printed circuit board 100 and the degree of freedom with respect to circuit design may be increased.

In addition, in the printed circuit board 100, according to the inventive concept, the signal traces 122 and the ground traces 132 facing each other are formed to overlap each other in the vertical direction (e.g., Z direction), and are also designed to extend in the same horizontal direction (e.g., in the +X or −X direction). In this case, because the ground trace 132 is disposed around the signal trace 122, a shielding effect for the signal trace 122 may be increased, and electrical reliability may be increased.

Ultimately, in the printed circuit board 100, according to the inventive concept, the signal through via 124 is designed to pass through the inside of the ground through via 134 in the vertical direction (e.g., Z direction), thereby securing electrical reliability and degrees of freedom with respect to circuit design.

Referring to FIG. 6, the printed circuit board 100 may have a substrate base 110, a signal wire 120A, and a ground wire 130A, and may include first, second, third, and fourth wiring layers L1, L2, L3, and L4.

In the printed circuit board 100A, according to the inventive concept, a plurality of through vias 124A and 134A electrically connecting the traces 122 and 132 disposed in the first, second, third, and fourth wiring layers L1, L2, L3, and L4 to each other may be formed in the substrate base 110. According to some embodiments, the plurality of through vias 124A and 134A may include a signal through via 124A and a ground through via 134A.

The plurality of through vias 124A and 134A may include a signal through via 124A connecting the signal trace 122 of the first wiring layer L1 to the signal trace 122 of the fourth wiring layer L4, and a ground through via 134A connecting the ground trace 132 of the second wiring layer L2 to the ground trace 132 of the third wiring layer L3.

In the printed circuit board 100A, according to the inventive concept, the signal through via 124A may be formed in a hollow cylinder shape having a first length in the vertical direction (e.g., Z direction) and a first diameter in the horizontal direction (e.g., X and Y directions). Compared to this, the ground through via 134A may be formed in a hollow cylinder shape having a second length less than the first length in the vertical direction (e.g., Z direction) and a second diameter greater than the first diameter in the horizontal direction (e.g., X and Y directions). For example, each of the signal through via 124A and the ground through via 134A may be formed in a hollow cylinder shape.

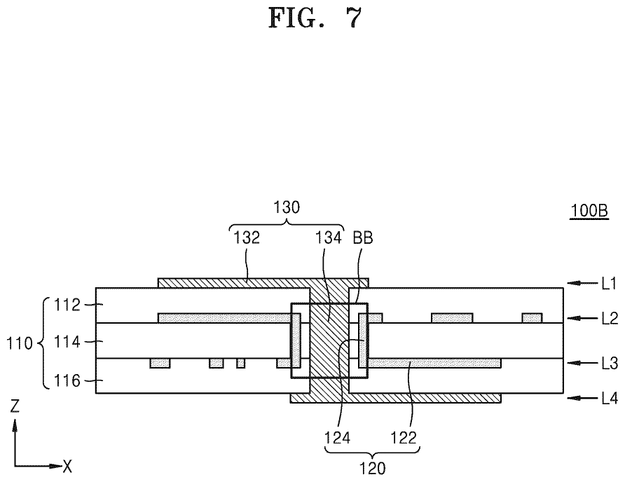

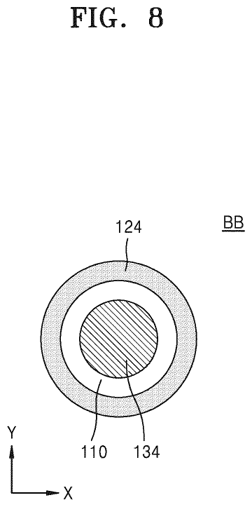

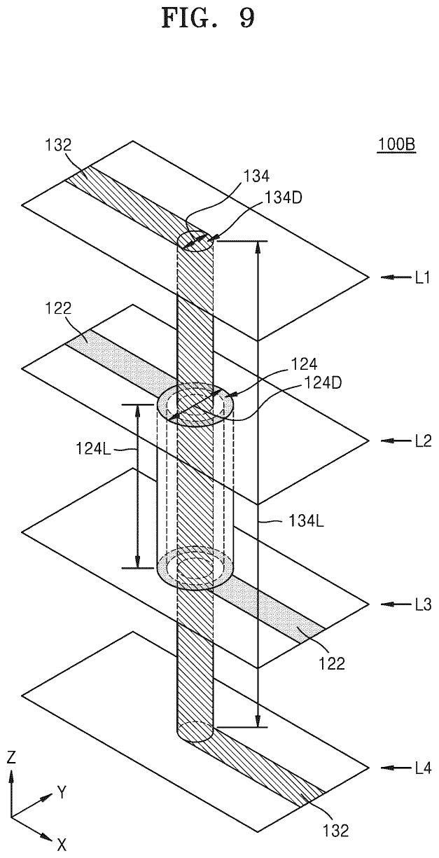

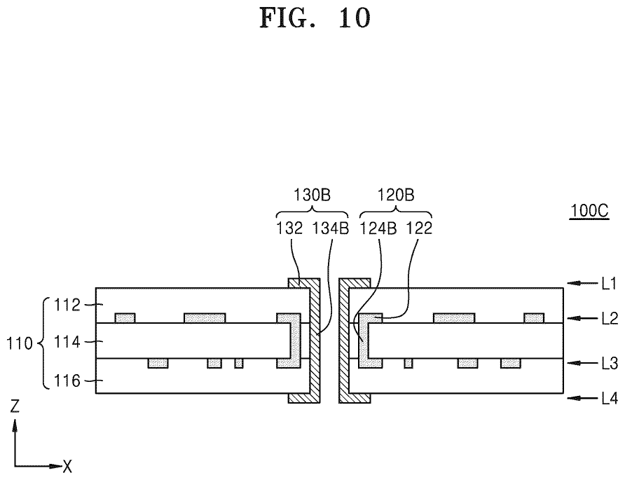

FIG. 7 is a cross-sectional view of a printed circuit board according to an embodiment, FIG. 8 is a plan view of a region BB of FIG. 7, and FIG. 9 is a perspective view of each wiring layer of FIG. 7. FIG. 10 is a cross-sectional view of a printed circuit board according to a derivative embodiment of FIG. 7.

Most of the components included within printed circuit boards 100B and 100C, which will be described below, and materials used to form the components are substantially the same as or similar to those described above with reference to FIGS. 1 through 5. Accordingly, for convenience of explanation, differences between the printed circuit boards 100B and 100C and the above-described printed circuit board 100 will be mainly described. To the extent that an element is not described in detail with respect to this figure, it may be understood that the element is at least similar to a corresponding element that has been described elsewhere within the present disclosure.

Referring to FIGS. 7 through 9 together, the printed circuit board 100B may have a substrate base 110, a signal wire 120, and a ground wire 130, and may include first, second, third, and fourth wiring layers L1, L2, L3, and L4.

In the printed circuit board 100B, according to the inventive concept, the ground traces 132 may be disposed on the first wiring layer L1 and the fourth wiring layer L4. The signal traces 122 may be disposed on the second wiring layer L2 and the third wiring layer L3. For example, the ground traces 132 may be disposed on uppermost and lowermost surfaces of the substrate base 110, and the signal traces 122 may be disposed inside the substrate base 110.

According to some embodiments, the ground trace 132 of the first wiring layer L1 and the signal trace 122 of the second wiring layer L2 may overlap each other in the vertical direction (e.g., Z direction), and may each extend in the first horizontal direction (e.g., X direction). The ground trace 132 of the fourth wiring layer L4 and the signal trace 122 of the third wiring layer L3 may overlap each other in the vertical direction (e.g., Z direction), and may each extend in the first horizontal direction (e.g., X direction). The ground trace 132 of the first wiring layer L1 and the ground trace 132 of the fourth wiring layer L4 may each extend in different horizontal directions (e.g., +X and −X directions). Accordingly, the signal trace 122 of the second wiring layer L2 and the signal trace 122 of the third wiring layer L3 may each extend in different horizontal directions (e.g., +X and −X directions).

In the printed circuit board 100B, according to the inventive concept, the plurality of through vias 124 and 134 may include a ground through via 134 connecting the ground trace 132 of the first wiring layer L1 to the ground trace 132 of the fourth wiring layer L4, and a signal through via 124 connecting the signal trace 122 of the second wiring layer L2 to the signal trace 122 of the third wiring layer L3.

According to some embodiments, the ground through via 134 may be formed in a cylindrical shape having a second length 134L in the vertical direction (e.g., Z direction) and a second diameter 134D in the horizontal direction (e.g., X and Y directions). Compared to this, the signal through via 124 may be formed in a hollow cylinder shape having a first length 124L less than the second length 134L in the vertical direction (e.g., Z direction) and a first diameter 124D greater than the second diameter 134D in the horizontal direction (e.g., X and Y directions). For example, each of the inner diameter and the outer diameter of the signal through via 124 may be designed to be greater than the second diameter 134D of the ground through via 134.

In the printed circuit board 100B, according to the inventive concept, the ground through via 134 may pass through the inside of the signal through via 124 in the vertical direction (e.g., Z direction). The signal through via 124 may be insulated from the ground through via 134. For example, the substrate base 110 or an insulating material (e.g., phenol resin, epoxy resin, or polyimide) included within the substrate base 110 may be disposed between the signal through via 124 and the ground through via 134.

Referring to FIG. 10, the printed circuit board 100C may have a substrate base 110, a signal wire 120B, and a ground wire 130B, and may include first, second, third, and fourth wiring layers L1, L2, L3, and L4.

In the printed circuit board 100C, according to the inventive concept, a plurality of through vias 124B and 134B electrically connecting the traces 122 and 132 disposed in the first, second, third, and fourth wiring layers L1, L2, L3, and L4 to each other may be formed in the substrate base 110. According to some embodiments, the plurality of through vias 124B and 134B may include a signal through via 124B and a ground through via 134B.

The plurality of through vias 124B and 134B may include a ground through via 134B connecting the ground trace 132 of the first wiring layer L1 to the ground trace 132 of the fourth wiring layer L4, and a signal through via 124B connecting the signal trace 122 of the second wiring layer L2 to the signal trace 122 of the third wiring layer L3.

In the printed circuit board 100C according to the inventive concept, the ground through via 134B may be formed in a hollow cylinder shape having a second length in the vertical direction (e.g., Z direction) and a second diameter in the horizontal direction (e.g., X and Y directions). Compared to this, the signal through via 124B may be formed in a hollow cylinder shape having a first length less than the second length in the vertical direction (e.g., Z direction) and a first diameter greater than the second diameter in the horizontal direction (e.g., X and Y directions). For example, each of the signal through via 124B and the ground through via 134B may be formed in a hollow cylinder shape.

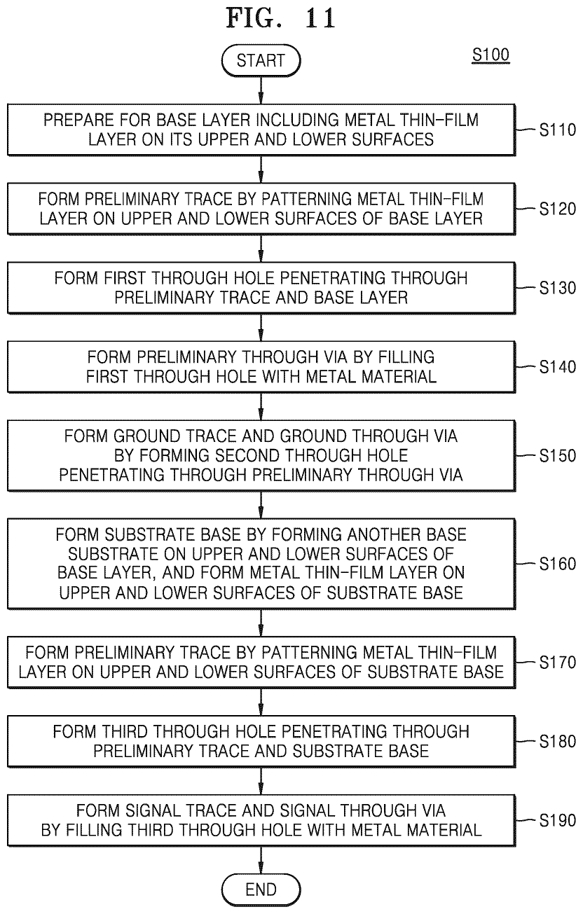

FIG. 11 is a flowchart of a method of manufacturing a printed circuit board device, according to an embodiment.

Referring to FIG. 11, a method S100 of manufacturing a printed circuit board device may include first through ninth operations S110 through S190.

When a certain embodiment may be implemented differently, a specific process order may be performed differently from the described order. For example, two consecutively described processes may be performed substantially at the same time or performed in an order opposite to the described order.

The method S100 of manufacturing a printed circuit board, according to the inventive concept, may include a first operation S110 of preparing for a base layer including a metal thin-film layer on its upper and lower surfaces. A second operation S120 of forming a preliminary trace by patterning the metal thin-film layer on the upper and lower surfaces of the base layer may be performed. A third operation S130 of forming a first through hole penetrating through the preliminary trace and the base layer may be performed. A fourth operation S140 of form a preliminary through via by filling the first through hole with a metal may be performed. A fifth operation S150 of forming a ground trace and a ground through via by forming a second through hole penetrating through the preliminary through via may be performed. A sixth operation S160 of forming a substrate base by forming another base substrate on the upper and lower surfaces of the base layer may be performed, and a metal thin-film layer may be formed on upper and lower surfaces of the substrate base. A seventh operation S170 of forming a preliminary trace by patterning the metal thin-film layer on the upper and lower surfaces of the substrate base may be performed. An eighth operation S180 of forming a third through hole penetrating through the preliminary trace and the substrate base may be performed. A ninth operation S190 of forming a signal trace and a signal through via by filling the third through hole with a metal may be performed.

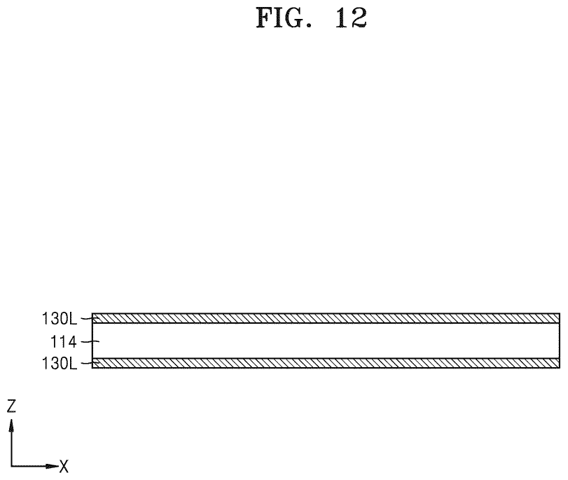

The respective technical characteristics of the first through ninth operations S110 through S190 will be described in detail with reference to FIGS. 12 through 20.

FIGS. 12 through 20 are cross-sectional views illustrating a method of manufacturing a printed circuit board, according to an embodiment.

Referring to FIG. 12, a second base layer 114 including a metal thin-film layer 130L on its upper and lower surfaces may be prepared. The second base layer 114 may be formed of at least one material selected from phenol resin, epoxy resin, and polyimide. The metal thin-film layer 130L may be formed of Cu foil, but embodiments are not necessarily limited thereto. For convenience of explanation, the second base layer 114 is first described. However, those skilled in the art will be able to fully understand the technical idea of the inventive concept.

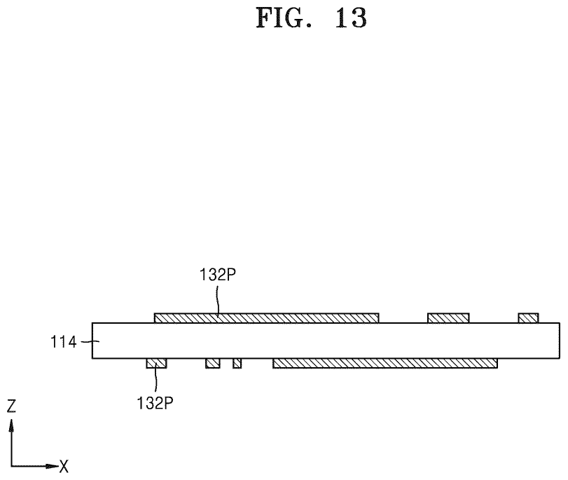

Referring to FIG. 13, a preliminary trace 132P may be formed by patterning the metal thin-film layer 130L (see FIG. 12) on the upper and lower surfaces of the second base layer 114. By etching the metal thin-film layer 130L (see FIG. 12), the preliminary trace 132P may be formed in a desired circuit pattern.

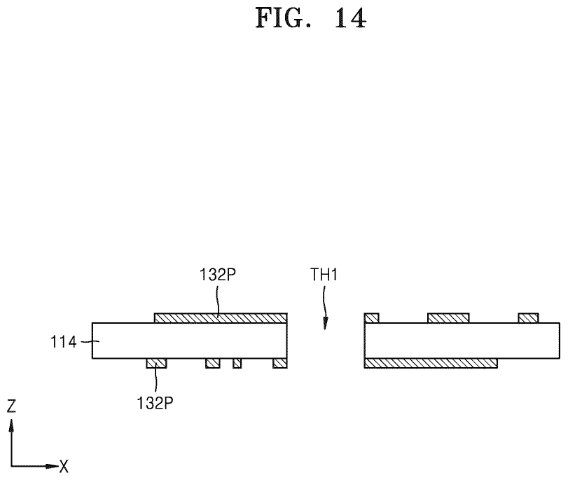

Referring to FIG. 14, a first through hole TH1 penetrating through the preliminary trace 132P and the second base layer 114 may be formed. The first through hole TH1 may be formed by laser processing or a drilling process using a CNC drilling machine.

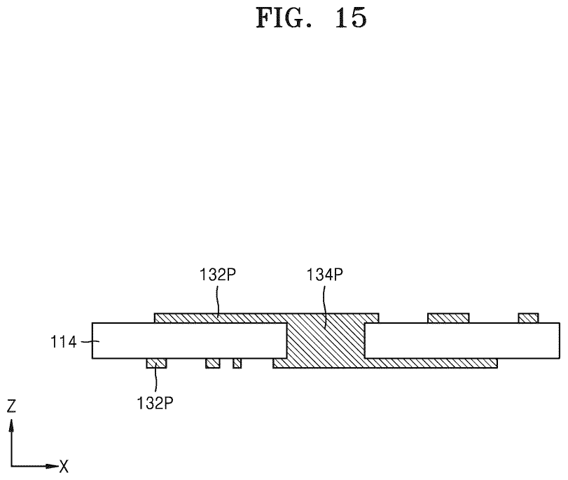

Referring to FIG. 15, the first through hole TH1 may be filled with a metal to form a preliminary through via 134P. The preliminary through via 134P may be formed of the same material as the ground trace 132.

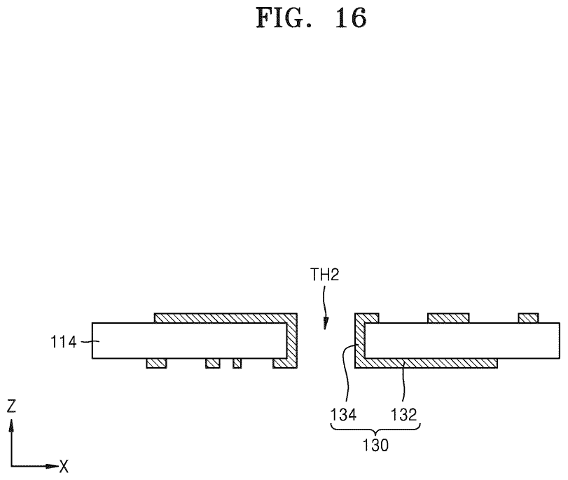

Referring to FIG. 16, a second through hole TH2 penetrating through the preliminary through via 134P may be formed. The second through hole TH2 may be formed by laser processing or a drilling process using a CNC drilling machine. In this manner, the ground trace 132 and the ground through via 134 may be formed.

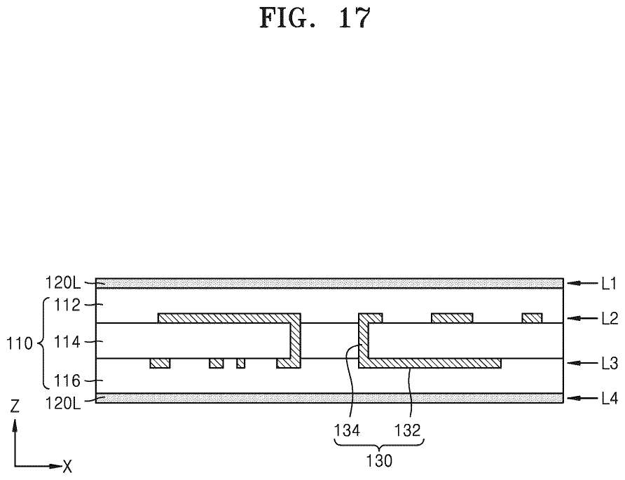

Referring to FIG. 17, the second through hole TH2 (see FIG. 16) may be filled with an insulating material, the first base layer 112 may be formed on the upper surface of the second base layer 114, and the third base layer 116 may be formed on the lower surface of the second base layer 114, thereby forming the substrate base 110. Next, a metal thin-film layer 120L may be formed on the upper and lower surfaces of the substrate base 110.

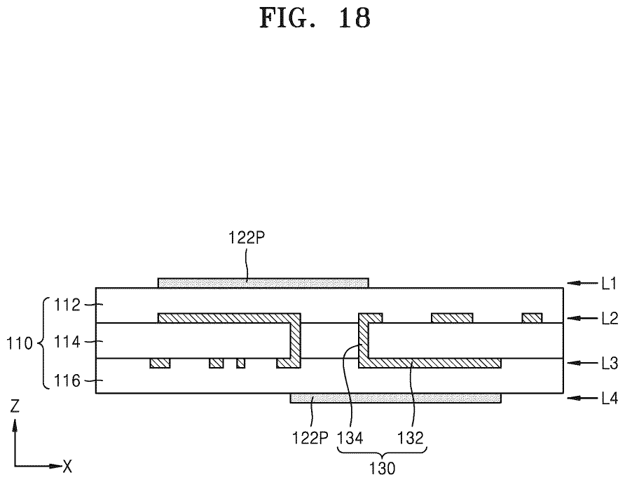

Referring to FIG. 18, a preliminary trace 122P may be formed by patterning the metal thin-film layer 120L (see FIG. 17) on the upper and lower surfaces of the substrate base 110. By etching the metal thin-film layer 120L (see FIG. 17), the preliminary trace 122P may be formed in a desired circuit pattern.

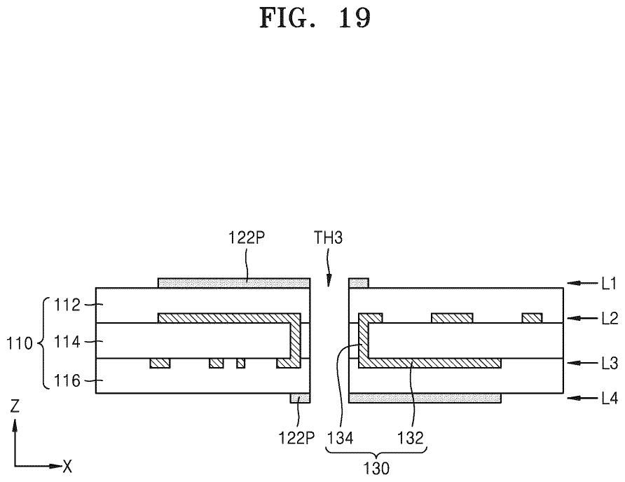

Referring to FIG. 19, a third through hole TH3 penetrating through the preliminary trace 122P and the substrate base 110 may be formed. The third through hole TH3 may be formed by laser processing or a drilling process using a CNC drilling machine.

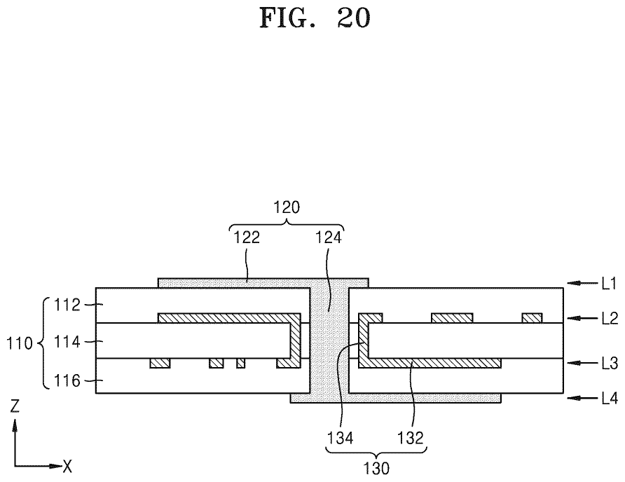

Referring to FIG. 20, the third through hole TH3 (see FIG. 19) may be filled with a metal to form the signal trace 122 and the signal through via 124. The signal through via 124 may be formed of the same material as the signal trace 122.

In the printed circuit board 100, according to the inventive concept, including the above-described manufacturing process, the signal through via 124 is disposed to pass through the inside of the ground through via 134 in the vertical direction (e.g., Z direction), thereby securing electrical reliability and degrees of freedom with respect to circuit design.

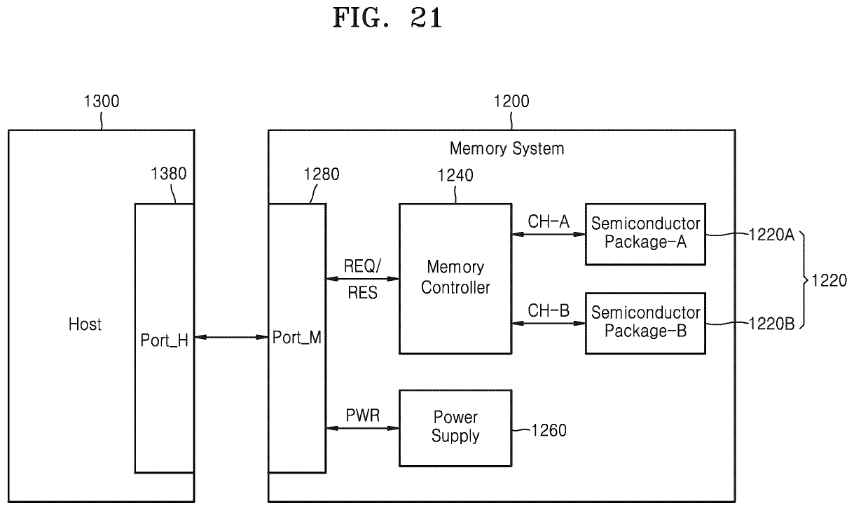

FIG. 21 is a block diagram of a detachable storage device 1200.

Referring to FIG. 21, the detachable storage device 1200 and a host 1300 may communicate with each other, and the detachable storage device 1200 may include a semiconductor package 1220, a memory controller 1240, a power supply device 1260, and a first port 1280.

The semiconductor package 1220 may include a plurality of memory chips each including a plurality of memory cells. The semiconductor package 1220 is a concept that includes cases where a memory chip is in a chip-scale form rather than a package form, and does not necessarily refer only to a general type semiconductor package.

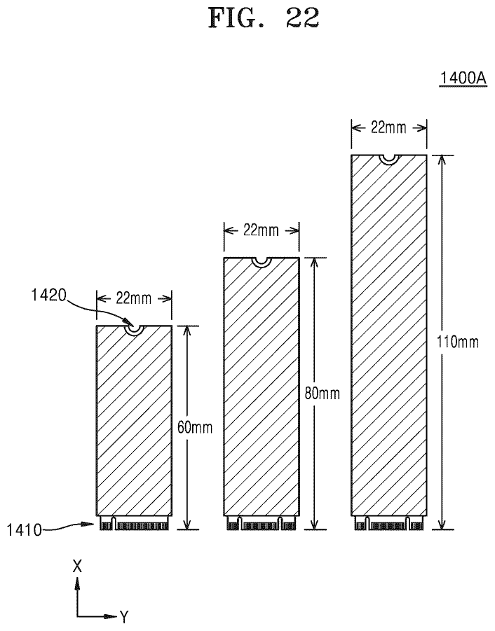

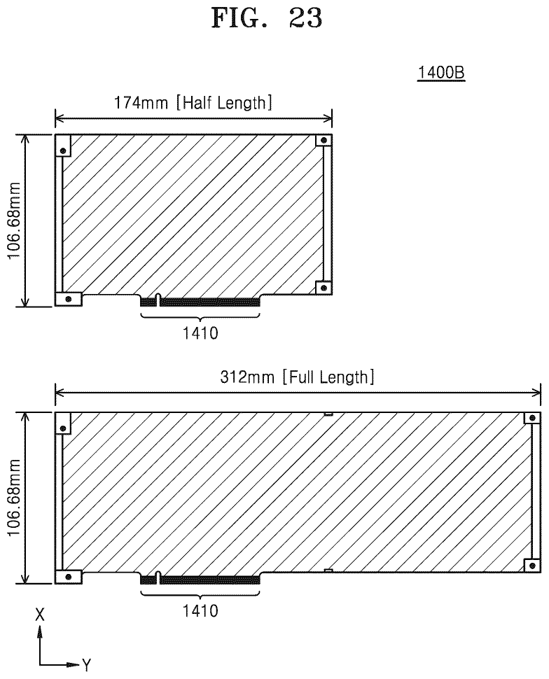

With technology developments in a semiconductor package process, a memory chip may be mounted on printed circuit boards 1400A and 1400B (see FIGS. 22 and 23), in a chip scale form rather than a package form. For example, the entire memory chip may be protected by a case, etc., or the memory chip may be directly encapsulated on the printed circuit boards 1400A and 1400B (see FIGS. 22 and 23) by using polymer resin rather than a molding compound.

For example, the memory chip may be a memory chip including a three-dimensional (3D) memory array. The 3D memory cell array may be formed monolithically on a physical level of a memory cell having a circuit formed on and/or in a silicon wafer as a circuit related with an operation of the memory cell, with an active region arranged on the silicon wafer. The term “monolithic” may mean that layers of each level that constitute a memory cell array are stacked directly on lower layers included in the memory cell array.

According to some embodiments, the 3D memory array may include NAND strings in a vertical structure in which at least one memory cell is positioned above another memory cell and auxiliary cells are arranged above or below the memory cells, and the at least one memory cell may include a charge trap layer.

According to embodiments, a plurality of memory cells may be planar NAND flash memory cells with a two-dimensional (2D) horizontal structure. According to embodiments, the plurality of memory cells may be non-volatile memory cells such as resistive random access memory (ReRAM) cells, phase change random access memory (PRAM) cells, or magnetic random access memory (MRAM) cells.

Each memory cell included in a memory cell array may store two-or-more-bit data. According to some embodiments, a memory cell included in a memory cell array may be a multi-level cell (MLC) that stores 2-bit data. According to embodiments, a memory cell included in a memory cell array may be a triple-level cell (TLC) that stores 3-bit data. According to embodiments, each memory cell included in a memory cell array may store four-or-more-bit data. A memory cell included in a string of a memory cell array may be used as a single-level cell (SLC) that stores 1-bit data.

A memory chip included within the semiconductor package 1220 may be connected to the memory controller 1240 through a channel group. For example, a semiconductor package-A 1220A may be connected to the memory controller 1240 through a channel group-A CH-A, and a semiconductor package-B 1220B may be connected to the memory controller 1240 through a channel group-B CH-B.

The drawing shows the two semiconductor packages 1200A and 1200B and the two channel groups CH-A and CH-B, but embodiments are not necessarily limited thereto. The detachable storage device 1200, according to the inventive concept, may include one semiconductor package and one channel group, or may include three or more semiconductor packages and three or more channel groups.

The memory controller 1240 may receive a request REQ from the host 1300 through the first port 1280, and may transmit a response RES to the host 1300 through the first port 1280. For example, the memory controller 1240 may receive a data read request from the host 1300 through the first port 1280, and, in response to the received data read request, the memory controller 1240 may read data stored in a memory chip included in the semiconductor package 1220 and transmit the read data to the host 1300 through the first port 1280.

The power supply device 1260 may receive power PWR from the host 1300 through the first port 1280, and may supply power to components included in the detachable storage device 1200, for example, to the semiconductor package 1220 and the memory controller 1240, based on the received power PWR.

The first port 1280 may include a plurality of pins, and may be connected to a second port 1380 of the host 1300. The number, sizes, and arrangement of pins may be determined based on an interface protocol through which the first port 1280 and the second port 1380 communicate with the host 1300. For example, the detachable storage device 1200 and the host 1300 may communicate with each other through at least one of various interface protocols, such as a universal serial bus (USB), a multi-media card (MMC), a peripheral component interconnect express (PCI-E), an advanced technology attachment (ATA), a serial-ATA, a parallel-ATA, a small computer system interface (SCSI), an enhanced small device interface (ESDI), and an integrated drive electronics (IDE), and the first port 1280 may include a plurality of pins according to interface protocols.

The detachable storage device 1200 may have various form factors so as to be able to mount the semiconductor package 1220 having various storage capacities. The detachable storage device 1200 may include a package substrate such as the printed circuit boards 1400A and 1400B (see FIGS. 22 and 23), and the semiconductor package 1220, the memory controller 1240, and the power supply device 1260, which are components of the detachable storage device 1200, may be mounted on the printed circuit boards 1400A and 1400B (see FIGS. 22 and 23).

The printed circuit boards 1400A and 1400B (see FIGS. 22 and 23) may include memory chip mounting areas spaced apart from each other, and, according to an environment or application in which the detachable storage device 1200 is used, the detachable storage device 1200 may be used flexibly by adjusting the memory capacity by mounting the semiconductor package 1220 in all of the memory chip mounting areas or by mounting the semiconductor package 1220 in only one of the memory chip mounting areas.

FIGS. 22 and 23 are diagrams illustrating examples of various form factors defining a printed circuit board mounted on the detachable storage device 1200 of FIG. 21.

For example, FIG. 22 shows various sizes of the printed circuit board 1400A according to the M.2 standard, and FIG. 23 shows various sizes of the printed circuit board 1400B according to the PCI card standard.

Referring to FIG. 22, as an example of the form factor, the M.2 standard may specify a thickness and left and right widths of the printed circuit board 1400A included within the storage device 1200 (see FIG. 21).

The M.2 standard may specify a length of the printed circuit board 1400A in the first horizontal direction (e.g., X direction) as 60 mm, 80 mm, or 110 mm, and a length of the printed circuit board 1400A in the second horizontal direction (e.g., Y direction) as 22 mm.

The M.2 standard may specify a port 1410. The port 1410 may be disposed on one side of the printed circuit board 1400A and may include a plurality of pins for communicating with the host 1300 (see FIG. 21). The plurality of pins may be exposed patterns, and the exposed patterns may be connected to sockets included in the host 1300 (see FIG. 21). The plurality of pins may include a conductive material, for example, a metal such as copper.

The M.2 standard may specify an indentation structure 1420 for mounting and fixing the detachable storage device 1200 (see FIG. 21) to the host 1300 (see FIG. 21). This form factor may include a semicircular indentation structure 1420 formed on the other side of the printed circuit board 1400A that is opposite to the port 1410. The exposed pattern may be formed on an edge of the indentation structure 1420, and, when mounted on the host 1300, may be connected to a conductor of the host 1300. For example, a pattern formed on the edge of the indentation structure 1420 may correspond to a ground node of the detachable storage device 1200 (see FIG. 21), and, when mounted on the host 1300, may be connected to a conductor correspond to a ground node of the host 1300.

Referring to FIG. 23, as an example of the form factor, the PCI card standard may specify a length of the printed circuit board 1400B included within the storage device 1200 (see FIG. 21), in the first horizontal direction (e.g., X direction), as 106.68 mm, and may specify a length of the printed circuit board 1400B in the second horizontal direction (e.g., Y direction) as 174 mm or 312 mm.

The length in the second horizontal direction (e.g., Y direction) specified by the PCI card standard defines a maximum length of the printed circuit board 1400B, and a length in the second horizontal direction (e.g., Y direction) of 174 mm may be referred to as a half length, and a length in the second horizontal direction (e.g., Y direction) of 312 mm may be referred to as a full length. For example, the printed circuit board 1400B of a half length may have a length in the first horizontal direction (e.g., X direction) of 106.68 mm and a length in the second horizontal direction (e.g., Y direction) of 174 mm or less. Ports 1410 at the half length and the full length may have the same locations and the same shapes.

According to the number of semiconductor packages mounted according to different specifications and memory capacity of various main boards included in various electronic devices, the printed circuit boards 1400A and 1400B may be manufactured to have various form factors so as to accommodate the various main boards.

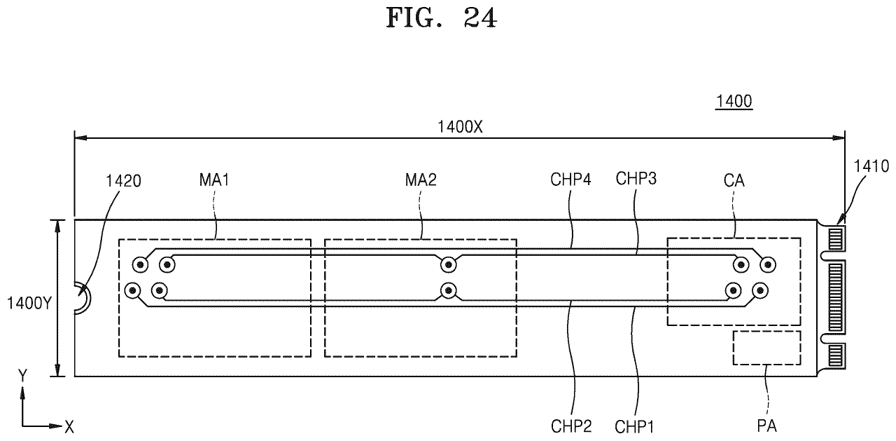

FIG. 24 is a plan view of a printed circuit board 1400 according to an embodiment.

Referring to FIG. 24, the printed circuit board 1400 is shown including a plurality of channel patterns, namely, first, second, third, and fourth channel patterns CHP1, CHP2, CHP3, and CHP4, which perform write and read operations.

The printed circuit board 1400, which is a board on which a semiconductor package is mounted, includes a base layer and a wiring portion. The wiring portion includes traces and through vias formed in the base layer.

According to some embodiments, the semiconductor package may be electrically connected to the first, second, third, and fourth channel patterns CHP1, CHP2, CHP3, and CHP4 in a first mounting area MA1, and the semiconductor package may be electrically connected to the second and third channel patterns CHP2 and CHP3 in a second mounting area MA2.

The printed circuit board 1400 may also include a power supply device area PA adjacent to a memory controller area CA. However, the arrangement of the power supply device area PA is not necessarily limited thereto.

In embodiments according to the inventive concept, traces and through vias for electrical connection of the first, second, third, and fourth channel patterns CHP1, CHP2, CHP3, and CHP4 may be formed. The traces may include the signal traces 122 and the ground traces 132 described above. The through vias may include the signal through vias 124 and the ground through vias 134 described above.

The printed circuit board 1400 may specify a length 1400X of the printed circuit board 1400 in the first horizontal direction (e.g., X direction) as 22 mm, and a length 1400Y of the printed circuit board 1400 in the second horizontal direction (e.g., Y direction) as 60 mm, 80 mm, or 110 mm. For example, the printed circuit board 1400 may be formed according to the M.2 standard. However, the inventive concept is not necessarily limited thereto.

While the inventive concept has been particularly shown and described with reference to embodiments thereof, it will be understood that various changes in form and details may be made therein without departing from the spirit and scope of the present disclosure.

What is claimed is:

1. A printed circuit board in which K base layers are stacked (where K is an integer of 3 or more), the printed circuit board, comprising:
K+1 traces disposed on respective upper and lower surfaces of each of the base layers and disposed on different vertical levels from a lowermost layer of the base layers to an uppermost layer of the base layers; and
through vias connecting traces disposed on different vertical levels to each other and each extending in a vertical direction passing through at least one of the base layers,
wherein the through vias comprise:
a first through via connecting the traces at the lowermost layer and the uppermost layer to each other; and
a second through via connecting respective traces at adjacent intermediate layers between the lowermost layer and the uppermost layer to each other, and
wherein the first through via passes through the inside of the second through via in the vertical direction, and the first through via is insulated from the second through via.

2. The printed circuit board of claim 1, wherein
the first through via comprises a signal through via connecting signal traces to each other, and
the second through via comprises a ground through via connecting ground traces to each other.

3. The printed circuit board of claim 2, wherein
the signal traces are disposed on an uppermost surface and a lowermost surface of the base layers, and
the ground traces are disposed at interfaces between the base layers.

4. The printed circuit board of claim 3, wherein
a signal trace at the lowermost layer and a ground trace at an intermediate layer, above the lowermost layer, overlap each other in the vertical direction and each extend in a first horizontal direction, and
a signal trace at the uppermost layer and a ground trace at an intermediate layer, below the uppermost layer, overlap each other in the vertical direction and each extend in a second horizontal direction different from the first horizontal direction.

5. The printed circuit board of claim 1, wherein
the first through via comprises a ground through via connecting ground traces to each other, and
the second through via comprises a signal through via connecting signal traces to each other.

6. The printed circuit board of claim 5, wherein
the ground traces are disposed on an uppermost surface and a lowermost surface of the base layers, and
the signal traces are disposed at interfaces between the base layers.

7. The printed circuit board of claim 6, wherein
a ground trace at the lowermost layer and a signal trace at an intermediate layer, above the lowermost layer, overlap each other in the vertical direction and each extend in a first horizontal direction, and
a ground trace at the uppermost layer and a signal trace at an intermediate layer, below the uppermost layer, overlap each other in the vertical direction and each extend in a second horizontal direction different from the first horizontal direction.

8. The printed circuit board of claim 1, wherein an insulating material included within the base layers is disposed between the first through via and the second through via.

9. The printed circuit board of claim 8, wherein
the first through via has a cylindrical shape having a first length in the vertical direction and a first diameter in a horizontal direction, and
the second through via has a hollow cylinder shape having a second length, less than the first length, in the vertical direction and a second diameter, greater than the first diameter, in the horizontal direction.

10. The printed circuit board of claim 8, wherein
the first through via has a hollow cylinder shape having a first length in the vertical direction and a first diameter in a horizontal direction, and
the second through via has a hollow cylinder shape having a second length, less than the first length, in the vertical direction and a second diameter, greater than the first diameter, in the horizontal direction.

11. A printed circuit board, comprising:
a substrate base including a plurality of base layers;
a plurality of traces disposed on respective upper and lower surfaces of each of the plurality of base layers; and
a plurality of through vias each passing through at least one of the plurality of base layers and contacting the plurality of traces,
wherein one of the plurality of through vias has a cylindrical shape, and another of the plurality of through vias has a hollow cylinder shape surrounding the cylindrical shape.

12. The printed circuit board of claim 11, wherein
the through via having a cylindrical shape comprises a signal through via connecting signal traces, among the plurality of traces, to each other, and
the through via having a hollow cylinder shape comprises a ground through via connecting ground traces, among the plurality of traces, to each other.

13. The printed circuit board of claim 12, wherein
the signal traces and the ground traces facing each other extend in a horizontal direction and overlap in a vertical direction, and
the signal through via has a smaller diameter than the ground through via.

14. The printed circuit board of claim 11, wherein
the through via having a cylindrical shape comprises a ground through via connecting ground traces, among the plurality of traces, to each other, and
the through via having a hollow cylinder shape comprises a signal through via connecting signal traces, among the plurality of traces, to each other.

15. The printed circuit board of claim 14, wherein
the signal trace and the ground trace facing each other extend in a horizontal direction and overlap in a vertical direction, and
the ground through via has a smaller diameter than the signal through via.

16. A semiconductor package, comprising:
a printed circuit board having a chip mounting area and a peripheral area surrounding the chip mounting area;
at least one semiconductor chip having a first surface and a second surface opposite to the first surface, including a chip pad disposed on the first surface, and being mounted in the chip mounting area such that the first surface faces an upper surface of the printed circuit board; and
a connection bump attached to the chip pad,
wherein the printed circuit board comprises:
base layers stacked in three or more layers;
traces disposed on respective upper and lower surfaces of the base layers and disposed on different vertical levels from a lowermost layer to an uppermost layer; and
through vias connecting the traces disposed on different vertical levels to each other and each extending in a vertical direction to pass through at least one of the base layers,
wherein the through vias comprise:
a first through via connecting traces at the lowermost layer and the uppermost layer to each other; and
a second through via connecting respective traces at adjacent intermediate layers between the lowermost layer and the uppermost layer to each other, and
wherein the first through via passes through an inside of the second through via in the vertical direction.

17. The semiconductor package of claim 16, wherein
the first through via comprises a signal through via connecting signal traces to each other,
the second through via comprises a ground through via connecting ground traces to each other,
the signal traces are disposed on an uppermost surface and a lowermost surface of the base layers, and
the ground traces are disposed at interfaces between the base layers.

18. The semiconductor package of claim 16, wherein
the first through via comprises a ground through via connecting ground traces to each other,
the second through via comprises a signal through via connecting signal traces to each other,
the ground traces are disposed on an uppermost surface and a lowermost surface of the base layers, and
the signal traces are disposed at interfaces between the base layers.

19. The semiconductor package of claim 16, wherein
the first through via has a cylindrical shape having a first length in the vertical direction and a first diameter in a horizontal direction,
the second through via has a hollow cylinder shape having a second length, less than the first length, in the vertical direction and a second diameter, greater than the first diameter, in the horizontal direction, and
an insulating material included within the base layers is disposed between the first through via and the second through via.

20. The semiconductor package of claim 16, wherein
a trace at the lowermost layer and a trace at an intermediate layer above the lowermost layer overlap each other in the vertical direction and each extend in a first horizontal direction, and
a trace at the uppermost layer and a trace at an intermediate layer, below the uppermost layer, overlap each other in the vertical direction and each extend in a second horizontal direction, different from the first horizontal direction.
